(19) United States
(12) Patent Application Publication
(10) Pub. No.: US 2009/0311855 A1
(43) Pub. Date: Dec. 17, 2009

(54) METHOD OF FABRICATING A GATE STRUCTURE

(76) Inventors: Richard A. Bruff, Wappingers Falls, NY (US); Richard A. Conti, Katonah, NY (US); Denise Pendleton-Lipinski, Poughkeepsie, NY (US); Amanda L. Tessier, Poughkeepsie, NY (US); Brian L. Tessier, Poughkeepsie, NY (US); Yun-Yu Wang, Poughquag, NY (US); Daewon Yang, Hopewell Junction, NY (US); Chienfan Yu, Highland Mills, NY (US)

Correspondence Address: HOFFMAN WARNICK LLC, 75 STATE ST, 14TH FL, ALBANY, NY, 12207, US

(21) Appl. No.: 12/544,425

(22) Filed: Aug. 20, 2009

Related U.S. Application Data
(62) Division of application No. 11/875,222, filed on Oct. 19, 2007.

(51) Int. Cl. H01L 21/28

(52) U.S. Cl. 438/587; 257/E21.19

(57) ABSTRACT

A method of fabricating a gate structure in a metal oxide semiconductor field effect transistor (MOSFET) and the structure thereof is provided. The MOSFET may be n-doped or p-doped. The gate structure, disposed on a substrate, includes a plurality of gates. Each of the plurality of gates is separated by a vertical space from an adjacent gate. The method deposits at least one dual-layer liner over the gate structure filling each vertical space. The dual-layer liner includes at least two thin high density plasma (HDP) films. The deposition of both HDP films occurs in a single HDP chemical vapor deposition (CVD) process. The dual-layer liner has properties conducive for coupling with plasma enhanced chemical vapor deposition (PECVD) films to form tri-layer or quadric-layer film stacks in the gate structure.

This application is a divisional of U.S. patent application Ser. No. 11/875,222, attorney docket number FIS920070152US1, filed on Oct. 19, 2007, currently pending.

### BACKGROUND

1. Technical Field

The disclosure relates to fabrication of a metal oxide semiconductor field effect transistor (MOSFET) and the structure thereof. More particularly, the disclosure relates to the fabrication of a gate structure where single-layer or dual-layer nitride liners are used to boost N-channel MOSFET (NFET) and P-channel MOSFET (PFET) performance, respectively.

2. Related Art

In the current state of the art, continued scaling of gate structures in complimentary metal oxide semiconductors (CMOS), use gate-spacer integration and strain engineering by one or more selective thin film deposition to enhance carrier mobility. Typically, plasma enhanced chemical vapor deposition (PECVD) is used to deposit a nitride film or films for forming a single or dual-layer nitride integration to boost NFET and PFET performance. With each film deposited as a single layer having uniform properties, the extent of control over conformality and adequate stress is limited. This limitation and the shape of the spacer having a vertical space extending from between the bases of adjacent gates tend to create voids in gate structures. The voids, which are subsequently filled by metal, result in electrical shorted paths at a contact level. This is particularly severe in the second liner deposition process, and more so in the case of PFET liners, which require compressive plasma enhanced nitride for enhancing carrier mobility.

FIG. 5 illustrates voids 30 formed in the deposition process of fill structure 40 for filing vertical space 25. Fill structure 40 may include barrier films (not shown) or dual-nitride films (not shown). Such typical fabrication processes use a constant film composition having a constant stress for forming the fill structure 40. Fill structure 40 is usually formed from a single PECVD film. When dual-layer nitride films are used for forming fill structure 40, multiple PECVD films are used. Since each layer of PECVD films shares uniform composition and stress properties, conformality variation in fill structure 40 is limited. This in turn compromises the ability for maintaining adequate composite stress.

Efforts to address the problem of void formation include tapering of spacers, replacing PECVD compressive nitride with high density plasma (HDP) chemical vapor deposition (CVD) nitride or alternating between deposition and reactive-ion-etching (RIE). However, these efforts have their limitations. The tapering of spacers may lead to over-etching of some areas because of the variable pitch of isolated and/or nested features. As to the use of HDP CVD nitride, the significant variable thickness with in a nominal 1000 Å across varied device structures poses a problem for RIE of the compressive nitride because of unavoidable over-etching in some areas. Alternating deposition and RIE is impractical because many cycles are required to prevent void formation. Even with the many cycles, avoidance of void formation is dependent on the profile after each cycle, which is very difficult to control in view of the number of cycles. Therefore the problem of void formation remains.

In view of the foregoing, it is desirable to develop an alternative method for depositing nitride films over a gate structure to obviate void formation in vertical space between adjacent gates within the gate structure.

### SUMMARY

A method of fabricating a gate structure in a metal oxide semiconductor field effect transistor (MOSFET) and the structure thereof is provided. The MOSFET may be n-doped or p-doped. The gate structure, disposed on a substrate, includes a plurality of gates. Each of the plurality of gates is separated by a vertical space from an adjacent gate. The method deposits at least one dual-layer liner over the gate structure filling each vertical space. The dual-layer liner includes at least two thin high density plasma (HDP) films. The deposition of both HDP films occurs in a single HDP chemical vapor deposition (CVD) process. The dual-layer liner has properties conducive for coupling with plasma enhanced chemical vapor deposition (PECVD) films to form tri-layer or quadric-layer film stacks in the gate structure.

A first aspect of the disclosure provides a gate structure comprising: a plurality of gates disposed on a substrate; and at least one dual-layer liner disposed on the plurality of gates and filling a vertical space between adjacent gates, the at least one dual-layer liner including an intrinsically stressed protective layer and an intrinsically stressed filling layer, the intrinsic stress of each of the intrinsically stressed protective layer and the intrinsically stressed filling layer being variable, and wherein the at least one dual-layer liner is formed of high density plasma (HDP) films.

A second aspect of the disclosure provides a method of fabricating a gate structure, the method comprising: forming a plurality of gates on a substrate; and depositing at least one dual-layer liner to fill a vertical space between adjacent gates, the at least one dual-layer liner including an intrinsically stressed protective layer and an intrinsically stressed filling layer, the intrinsic stress of each of the intrinsically stressed protective layer and the intrinsically stressed filling layer being variable, and wherein the depositing is a single step deposition of high density plasma (HDP) films.

A third aspect of the disclosure provides a gate structure comprising: a plurality of gates disposed on a substrate; and at least one tri-layer film stack disposed on the plurality of gates and filling a vertical space between adjacent gates, the at least one tri-layer film stack including at least one dual-layer liner and at least a layer selected from a group consisting of: a capping layer and a base layer, wherein the at least one dual-layer liner includes an intrinsically stressed protective layer and an intrinsically stressed filling layer, the intrinsic stress of each of the intrinsically stressed protective layer and the intrinsically stressed filling layer being variable, and wherein the at least one dual-layer liner is formed of high density plasma (HDP) films.

A fourth aspect of the disclosure provides a gate structure comprising: a plurality of gates disposed on a substrate; and at least one quadric-layer film stack disposed on the plurality of gates and filling a vertical space between adjacent gates, the at least one quadric-layer film stack including at least one dual-layer liner, a base layer and a capping layer, wherein the at least one dual-layer liner includes an intrinsically stressed protective layer and an intrinsically stressed filling layer, the intrinsic stress of each of the intrinsically stressed protective layer and the intrinsically stressed filling layer being variable, and wherein the protective layer and filling layer is formed of a high density plasma (HDP) film, and wherein the at least one dual-layer liner is between the base layer and the capping layer, wherein each of the protective layer, filling layer, base layer and capping layer include an intrinsic stress.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 illustrates a cross-sectional view of an embodiment of a gate structure in a MOSFET.

FIG. 2 illustrates a cross-sectional view of another embodiment of a gate structure in a MOSFET.

FIG. 3 illustrates a cross-sectional view of an alternative embodiment of a gate structure in a MOSFET.

FIG. 4 illustrates a cross-sectional view of yet another embodiment of a gate structure in a MOSFET.

FIG. 5 illustrates a cross-sectional view of a prior art gate structure in a MOSFET with a barrier layer disposed over the gate structure.

The accompanying drawings are not to scale, and are incorporated to depict only typical aspects of the disclosure. Therefore, the drawings should not be construed in any manner that would be limiting to the scope of the disclosure. In the drawings, like numbering represents like elements between the drawings.

### DETAILED DESCRIPTION

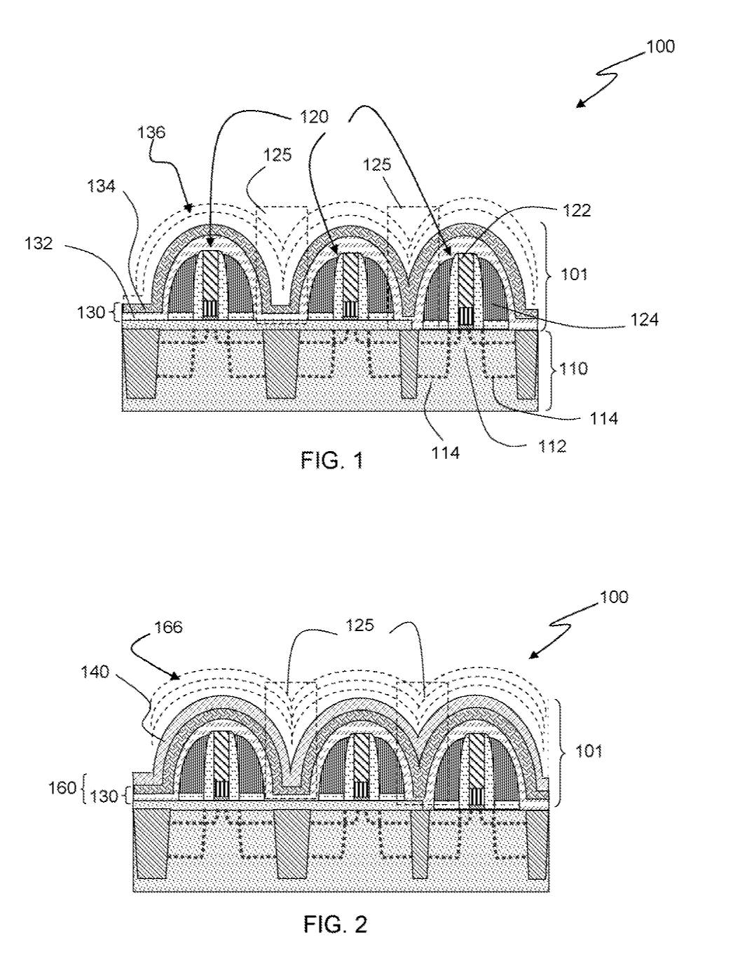

Embodiments depicted in the drawings in FIGS. 1-4 illustrate the resulting structure of the different aspects of fabricating a gate structure 101 in a metal oxide semiconductor field effect transistor (MOSFET) 100 with the use of high density plasma (HDP).

FIG. 1 illustrates an exemplary embodiment of a gate structure 101 in a MOSFET 100. Gate structure 101 includes gates 120 disposed on substrate 110. Gates 120 are separated by vertical space 125 formed therebetween, which may be of the same depth as gates 120. Substrate 110 includes channel 112 that divides source-drain region 114. Each gate 120 includes gate electrode 122 and spacer 124, and is disposed directly above corresponding channel 112 and source-drain region 114.

Also illustrated in FIG. 1 is a dual-layer liner 130 which includes of a protective layer 132 and a filling layer 134. Protective layer 132 is a high density plasma (HDP) film deposited at a bias power of, at maximum, approximately 300 W. Protective layer 132 primarily provides protection of gates 120 from damage by high power deposition of high stress films, for example, but is not limited to filling layer 134. However, the deposition of protective layer 132 also provide bottom-up fill of vertical space 125. Filling layer 134 is also a HDP film deposited at a high bias power of approximately 1000 W to approximately 2000 W to maximize bottom-up fill of vertical space 125.

Typically, the desired thickness of dual-layer liner 130 (i.e., the combined thickness of protective layer 132 and filling layer 134) may range from, but is not limited to, for example, approximately 500 Å to approximately 1300 Å. The thickness of each of protective layer 132 and filling layer 134 may be varied or adjusted to achieve this desired thickness. Protective layer 132 usually has a thickness ranging from approximately 100 Å to approximately 200 Å. Filling layer 134 usually has a thickness of approximately 300 Å to approximately 1200 Å. The HDP films may include, but are not limited to: nitride, oxide, doped nitride or doped oxide or any combination thereof. The nitride may be doped with, but is not limited to, for example, germanium, phosphorous or boron.

The deposition of dual-layer liner 130 is performed in a single deposition step, where protective layer 132 and filling layer 134 of differing properties and purposes are deposited to provide conformality and stress variation. For example, protective layer 132 may have a density range of approximately 2.80 g/cc to approximately 2.85 g/cc and filling layer 134 may have a density range of approximately 2.5 g/cc or less. Additionally, protective layer 132 may have a reflective index that range from approximately 1.95 to approximately 1.97, while filling layer 134 may have a reflective index of greater than approximately 1.89. Multiple layers 136 of dual-layer liner 130 may be formed with the single deposition step, which occurs after completion of standard processes for the formation of gates 120 following reactive-ion etching (RIE). Dual-layer liner 130 is deposited using HDP chemical vapor deposition (CVD) to fill any vertical space 125 between spacers 124 in a bottom-up manner from the base of gates 120. The deposition of dual-layer liner 130 levels out the bottom of vertical space 125 and provides for subsequent plasma enhanced chemical vapor deposition (PECVD) of nitride layers.

FIG. 2 illustrates another exemplary embodiment of gate structure 101 in MOSFET 100 where, in addition to dual-layer liner 130, a capping layer 140 is disposed over filling layer 134 forming tri-layer film stack 160. Capping layer 140 is formed from currently known or later developed PECVD techniques. Capping layer 140 is usually deposited at a power ranging from approximately 300 W to approximately 1500 W depending on the desired thickness and the reliability requirement to be met. Capping layer 140 is used to make up the desired thickness of a tri-layer film stack 160. The desired thickness of tri-layer film stack 160 is the combined thickness of dual-layer liner 130 and capping layer 140. The desired thickness of tri-layer film stack 160 may range from, but is not limited to, for example, approximately 500 Å to approximately 1300 Å. The thickness of capping layer 140 may vary according to the desired thickness of tri-layer film stack 160 and the thickness of deposited dual-layer liner 130. Usually, the thickness of capping layer 140 may range from, but is not limited to, for example, approximately 100 Å to approximately 1100 Å. Each of protective layer 132 and filling layer 134 usually has a thickness that range from, but are not limited to, for example, approximately 100 Å to approximately 200 Å. Protective layer 132 is deposited at medium bias (high frequency) power of no greater than approximately 300 W in order to provide a thin HDP nitride film for filling vertical space 125 in a bottom-up manner. Medium bias (high frequency) power is also selected to avoid damage to any low temperature oxide liner (LTO) (not shown) that exist over gate structure 101. Following the deposition of protective layer 132, filling layer 134 is deposited at high bias (high frequency) power ranging from approximately 1000 W to approximately 2000 W to maximize bottom-up fill of vertical space 125. This subsequent very high bias power for depositing filling layer 134 does not damage any LTO in view of the coating formed by protective layer 132.

For example, in the case of a PFET, protective layer 132 is a HDP nitride film of a thickness of approximately 150 Å deposited at a bias power of approximately 300 W without damaging topography of any LTO (not shown) that exist as part of gate structure 101. Filling layer 134 is then deposited at a high bias power of approximately 1750 W. LTO (not shown) is not damaged in view of deposition of protective layer 132 as a coating over the LTO (not shown). Subsequent to the deposition of filling layer 134, PECVD follows to form capping layer 140. Dual-layer liner 130 and capping layer 140 forms tri-layer film stack 160 in vertical space 125. Tri-layer film stack 160 leaves a void-free region and does not pose any difficulty for subsequent processing with RIE and exhibits high uniformity in thickness. HDP nitride film maybe selected as protective layer 132 and filling layer 134 because the deposition of HDP nitride film offers a high compressive nitride with compression ranging from approximately 0.7 GPa to approximately 3.5 GPa. The high compressive nitride facilitates composite stress in tri-layer film stack 160. Furthermore, the use of HDP easily integrates into the manufacturing process just before the next standard step (i.e., RIE) of the process. The deposition process for forming tri-layer film stack 160 demonstrates high repeatability, where multiple layers of tri-layer film stack 166 or 176 may be formed.

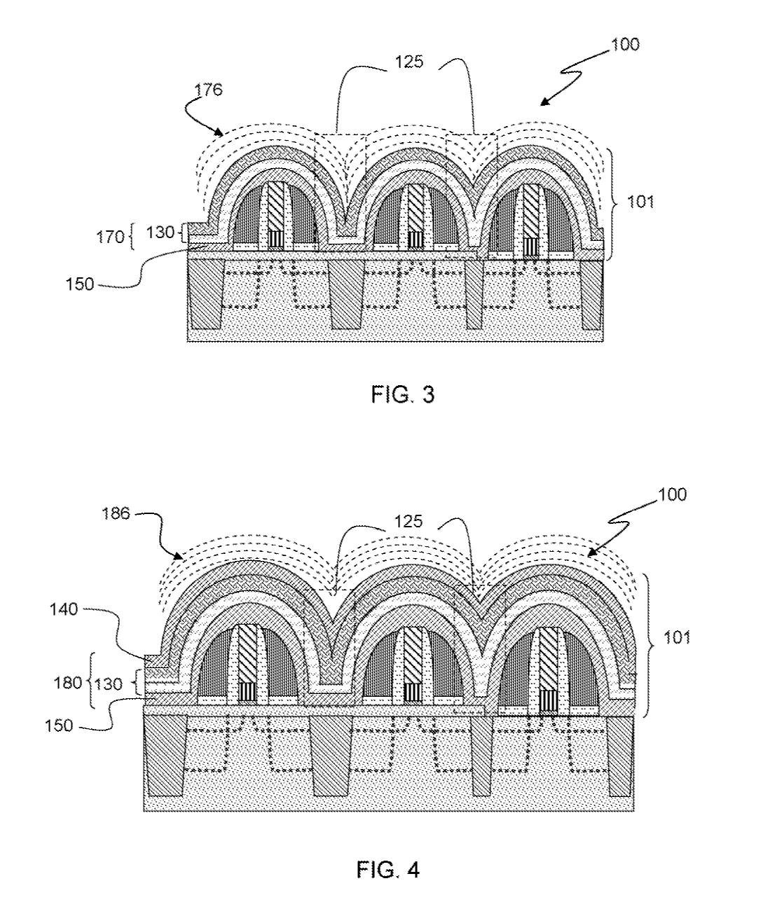

FIG. 3 illustrates an alternative embodiment of gate structure 101 in MOSFET 100, where following the formation of gates 120, deposition of a base layer 150 is performed prior to the single step deposition of dual-layer liner 130 to form a tri-layer film stack 170. Base layer 150 is a PECVD thin film formed from currently known or later developed PECVD techniques. Base layer 150 usually has a thickness that may range from, but is not limited to, for example, approximately 80 Å to approximately 120 Å. Protective layer 132 has a thickness that may range from, but is not limited to, for example, approximately 100 Å to approximately 200 Å. Filling layer 134 has a thickness that may range from, but is not limited to, for example, approximately 200 Å to approximately 1100 Å. Tri-layer film stack 170 formed in this embodiment is such that a PECVD thin film coats any LTO (not shown) that exists as part of gate structure 101. The desired thickness of tri-layer film stack 170 (i.e., combined thickness of base layer 150 and dual-layer liner 130) may range from, but is not limited to, for example, approximately 500 Å to approximately 1300 Å. As with the previous embodiments, once base layer 150 is formed, thickness of dual-layer liner 130, especially filling layer 134 therein may vary to make up the thickness of tri-layer film stack 170.

In another alternative embodiment shown in FIG. 4, gate structure 101 in MOSFET 100 includes base layer 150, dual-layer liner 130 and capping layer 140. Base layer 150 and capping layer 140 are both deposited using currently known PECVD or later developed techniques. Dual-layer liner 130 is formed using currently known or later developed HDP CVD deposition of protective layer 132 and filling layer 134 in a single deposition step. The combination of dual-layer liner 130 between base layer 150 and capping layer 140 form a quadric-layer film stack 180. Thickness of the respective layers so formed is such that base layer 150 has a thickness that may range from but is not limited to, for example, approximately 80 Å to approximately 120 Å. Protective layer 132 has a thickness ranging from, but is not limited to, for example, approximately 0 Å to approximately 100 Å. Filling layer 134 has a thickness that may range from, but is not limited to, for example, approximately 200 Å to approximately 500 Å. Capping layer 140 has a thickness of approximately 0 Å to approximately 500 Å. The desired thickness of quadric-layer film stack 180 (i.e., combined thickness of base layer 150, dual-layer liner 130 and capping layer 140) may range from, but is not limited to, for example, approximately 500 Å to approximately 1300 Å. In order to adhere to the desired thickness, once base layer 150 is deposited, protective layer 132 may be omitted or at most be of a thickness of 100 Å. The thickness of filling layer 134 and capping layer 140 may vary accordingly to make up the thickness of quadric-layer film stack 180. Multiple layers of quadric-layer 186 may be formed by repeating the same deposition processes.

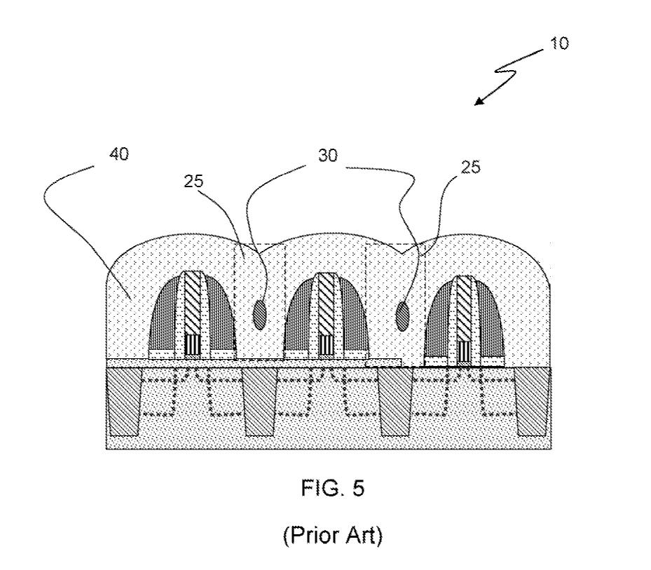

According to the fabrication process of the various embodiments of gate structure 101 in MOSFET 100, illustrated in FIGS. 1-4, the bias power applied in the HDP deposition of the nitride film is optimized to allow compatibility with various types of RIE. In addition to avoiding damage to any existing LTO on the gate structure 101, the optimized bias power also provides substantial bottom-up instead of sidewall deposition unlike the fabrication process of a typical MOSFET 10 (FIG. 5) in the prior art. Currently proposed fabrication process of dual-layer liner 130, illustrated in FIGS. 1-4, provides a more compatible conformality with gate structure 101, and stress that can be varied to meet channel mobility requirements of a given technology. The inclusion of base layer 150 and/or capping layer 140, illustrated in FIGS. 2-4, enhance conformality and mitigate thin sidewall deposition. Furthermore, the combination of base layer 150 and/or capping layer 140 with dual-layer liner 130 form tri-layer film stack 160 and 170 or quadric-layer film stack 180. PECVD base layer 150 and/or capping layer 140 in tri-layer film stack 160 and 170 or quadric-layer film stack 180 form a barrier against mobile ions, which may otherwise diffuse through any LTO (not shown) disposed on gate structure 101 and impede performance.

Each of protective layer 132, filling layer 134, within dual-layer liner 130, capping layer 140 and base layer 150 for forming tri-layer film stack 160, 170 and/or quadric-layer 180, may be intrinsically stressed. Typically, protective layer 132 may have an intrinsic compressive stress ranging from approximately 300 MPa to approximately 3300 MPa. While filling layer 134 may have an intrinsic compressive stress ranging from approximately 2000 MPa to approximately 3300 MPa. The intrinsic compressive stress of protective layer 132 and filing layer 134 may be varied such that a desired resultant composite compressive stress of the dual-layer liner 130 is achieved. The intrinsic stress may be varied to achieve desired net composite stress/strain in a multilayer film stack over a device channel through adjustment of thickness ratio between the individual layers. A multilayer film stack may include but is not limited to, for example, dual-layer liner 130, tri-layer film stack 160,170, quadric-layer film stack 180, multiple layers of dual-layer liner 136, multiple layers of trip-layer film stack 166,176 and multiple layers of quadric-layer film stack 186.

The foregoing description of various aspects of the disclosure has been presented for purposes of illustration and description. It is not intended to be exhaustive or to limit the scope of the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of fabricating a gate structure, the method comprising:
forming a plurality of gates on a substrate; and
depositing at least one dual-layer liner to fill a vertical space between adjacent gates, the at least one dual-layer liner including an intrinsically stressed protective layer and an intrinsically stressed filling layer, the intrinsic stress of each of the intrinsically stressed protective layer and the intrinsically stressed filling layer being variable,
wherein the depositing is a single step deposition of high density plasma (HDP) film.

2. The method of claim 1, wherein the depositing of the protective layer is at a maximum power of approximately 300 W; and the depositing of the filling layer is at a power ranging from approximately 1000 W to approximately 2000 W.

3. The method of claim 1, further comprising depositing a capping layer on the at least one dual-layer liner.

4. The method of claim 3, wherein the depositing of the protective layer is at a maximum power of approximately 300 W; the depositing of the filling layer is at a power ranging from approximately 1000 W to approximately 2000 W; and the depositing of the capping layer is at a power ranging from approximately 300 W to approximately 1500 W.

5. The method of claim 3, further comprising depositing a base layer before depositing the at least one dual-layer liner.

6. The method of claim 5, wherein the depositing of the base layer is at a power ranging from approximately 300 W to approximately 1500 W, the depositing of the protective layer is at a maximum power of approximately 300 W; the depositing of the filling layer is at a power ranging from approximately 1000 W to approximately 2000 W; and the depositing of the capping layer is at a power ranging from approximately 300 W to approximately 1500 W.

7. The method of claim 1, further comprising depositing a base layer before depositing the at least one dual-layer liner.

8. The method of claim 7, wherein the depositing of the base layer is at a power ranging from approximately 300 W to approximately 1500 W, the depositing of the protective layer is at a maximum power of approximately 300 W; and the depositing of the filling layer is at a power ranging from approximately 1000 W to approximately 2000 W.
